(19) United States
(12) Patent Application Publication
(10) Pub. No.: US 2007/0051940 A1
(43) Pub. Date: Mar. 8, 2007

(54) Device and method for determining the physical condition of an animal

(76) Inventors: Wolfgang Clemens, Puschendorf (DE); Walter Fix, Nurnberg (DE); Axel Gerlt, Furth (DE); Andreas Ullmann, Zirndorf (DE)

Correspondence Address: CARELLA, BYRNE, BAIN, GILFILLAN, CECCHI,;STEWART & OLSTEIN, 5 BECKER FARM ROAD, ROSELAND, NJ, 07068, US

(21) Appl. No.: 10/543,561

(22) PCT Filed: Jan. 14, 2004
(86) PCT No.: PCT/EP04/00021

§ 371 Date: May 2, 2006

(30) Foreign Application Priority Data
Jan. 29, 2003 (DE) 103 03 445.5

(51) Int. Cl. H01L 29/08

(52) U.S. Cl. 257/40

(57) ABSTRACT

Organic memory unit and driver circuit therefor The invention relates to organic memory units and driver circuits therefor. The organic memory units have a layer of bistably switchable material or comprise a circuit in which two OFETs are connected in series and one OFET is connected in parallel with a capacitor on the low potential side thereof such that the capacitor is connected in parallel with the discharge OFET and is charged by the second OFET.

The invention relates to an organic memory unit and a driver circuit therefor.

Organic-based memory units have been disclosed, for example, in DE 10045192.6.

For many applications which are based on organic electronics, organic, write-once or rewritable memories are needed (eg in RFID tags or in simple electronic games). Above all, non-volatile memories are indispensable for, say, electronic bar-codes or watermarks.

Passive organic memory units are known which are based on ferroelectric material (Electronic Design, Aug. 20, 2001, page 56) (“polymeric ferroelectric RAM”, inter alia, is presented in this article). This involves memory-matrix constructional systems which are non-volatile, but also such systems as are controlled by external circuits, preferably conventional silicon circuits.

A disadvantage here is the control of the memory units, which operates by means of an external circuit.

It is therefore an object of the present invention to provide an organic-based non-volatile memory unit, which is readable without an external circuit and can be written reversibly.

The present invention relates to an organic-based memory unit which comprises at least one organic functional layer, in which a property (such as the dielectric constant, electrical conductivity, magnetic permeability) can be switched bistably. The invention further relates to an organic capacitance memory which is realized by means of a circuit arrangement including a capacitor, wherein two OFETs are connected in series and a capacitor is connected in parallel with one of the OFETs, this OFET being the discharge OFET.

An organic memory unit comprises at least the following functional layers: lower electrode(s), an insulator, optionally having integrated storage material, and an upper electrode.

According to one embodiment of the invention, the memory unit is written simply by increasing the voltage applied to the upper electrode.

According to another embodiment, the memory unit is integrated in an organic field effect transistor (OFET).

According to another embodiment, a capacitor assembly serves as a memory.

For the memory unit, a material is needed in which a certain property (eg electrical conductivity, dielectric constant or magnetic permeability) can be switched bistably by external influences, that is to say, at least two states can be actively created and these states remain stable in time. Moreover, the organic memory unit includes a further component by means of which the state of the bistable material can be read and altered. It is preferred that reading does not alter the state of the bistable material.

The invention is described in greater detail below with reference to three figures, which illustrate embodiments of the invention.

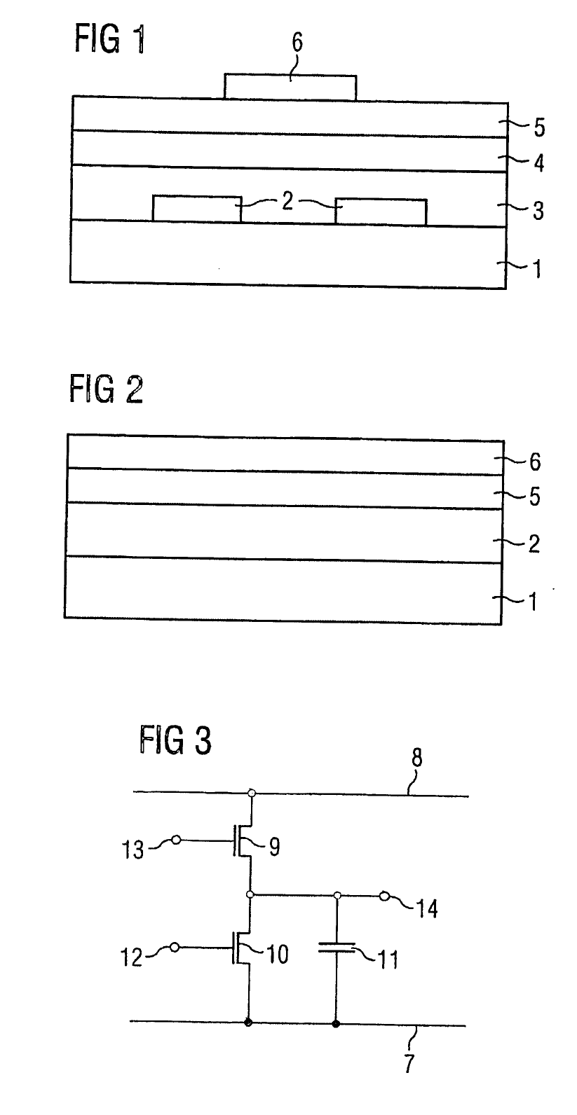

FIG. 1 shows a memory which is integrated in an OFET,

FIG. 2 shows a capacitor acting as a memory, and

FIG. 3 shows a circuit arrangement including a capacitor acting as a memory.

In FIG. 1, an OFET is illustrated diagrammatically in cross-section and shows a substrate 1, for example a polyester film to which source/drain electrodes 2 have been applied in structured form. This can be carried out, for example, by printing or by means of photolithography. Lower electrodes 2 (source/drain) are embedded in a semiconductor layer 3, which is covered by an insulator layer 4. These layers can in turn be applied by printing, knife coating, centrifugal deposition or spraying. Since some of the materials whose physical properties such as the dielectric constant, electrical conductivity, and/or magnetic permeability can be switched bistably also have insulating properties, the memory can be identical to insulator layer 4. A layer 5 in the OFET assembly is then unnecessary and the gate electrode will be connected directly to insulator layer 4. On the other hand, however, an additional, optionally very thin layer 5 can also be present, which consists of the bistably switchable material and which is situated below or above insulator layer 4. Finally, an upper gate electrode 6 is disposed either on the insulator layer of bistably switchable material 4 or on layer 5 attached thereto. The state of the bistably switchable layer 5 can be read by applying a voltage to the source/drain electrodes. The state in layer 5 is programmed by applying a voltage to gate electrode 6.

FIG. 2 shows how a capacitor assembly can be employed as a memory: dielectric layer 5 having a variable dielectric constant is sandwiched between lower electrode 2 and upper electrode 6. Thus the material having an adjustable dielectric constant in layer 5 lies between two conductive layers—lower electrode 2 and upper electrode 6, on substrate 1. The dielectric constant can be switched by means of high voltages. The memory state can then be determined by the charging current of the capacitor, which is, of course, high or low according to the dielectric constant.

The material having a switchable dielectric constant used can be, for example, polyvinylidene dichloride (PVDC) or polyvinylidene difluoride (PVDF). In the case of these materials, the dielectric constant is switched by high electrical fields.

FIG. 3 shows a circuit arrangement having a capacitor acting as a memory. This organic memory unit or this organic capacitance memory can be realized without special material using the following circuit: two OFETs 9, 10 are connected in series and a capacitor, or more precisely, a storage capacitor 11, is connected in parallel with discharge OFET 10. The charge OFET is designated by 9 and the discharge OFET by 10. The supply voltage is applied to 7 and 8. The supply voltage is low at 7 and the supply voltage is high at 8. Capacitor 11 can be charged by means of a short impulse to input 13 and discharged by means of a short impulse to input 12. Input 12 is connected to discharge OFET 10 and input 13 to charge OFET 9. The state of the memory can be queried at output 14 of the memory unit, for example by means of a further OFET.

The invention relates to organic memory units and driver circuits therefor. The organic memory units have a layer of bistably switchable material or comprise a circuit in which two OFETs are connected in series and one OFET is connected in parallel with a capacitor on the low potential side thereof such that the capacitor is connected in parallel with the discharge OFET and is charged by the second OFET.

The main advantage of the organic memory units presently described is that they can be readily included in organic or polymer-electronic circuits, because they can be easily integrated into the production processes due to their simple construction. The production processes can be readily combined. A further advantage lies in the simplicity of control of the memory units, a further important advantage being that the memory units are non-volatile.

1. An organic-based memory unit comprising,
first and second conductors; and
at least one organic bistably switchable functional layer of which a property including at least one of dielectric constant electrical conductivity and magnetic permeability is bistably switchable, the functional layer being ohmically coupled to and between the first and second conductors.

2. A memory unit as defined in claim 1, further including an organic field effect transistor including said first and second conductors and an insulator coupled to the first and second conductors wherein said bistably switchable organic functional layer is integrated into said organic field effect transistor in addition to the insulator layer.

3. A memory unit as defined in claim 1, wherein said bistably switchable organic functional layer has an electrical insulating property further including an organic field effect transistor including said first and second conductors wherein said functional layer forms an insulator layer in said transistor.

4. A memory unit as defined in claim 2 or claim 3, wherein the property of said bistably adjustable functional layer is said dielectric constant and wherein the dielectric constant is arranged to changes in value in response to the application of an electric potentials to the functional layer.

5. An organic capacitance memory cell, comprising:
a circuit arrangement including a capacitor; and two OFETs connected in series, the two OFETs forming respective charge and discharge OFETs with respect to the capacitor;
the capacitor being i connected in parallel with the discharge OFET.

6. The organic capacitance memory cell of claim 5 wherein the OFETs are coupled to a supply voltage.

7. The organic capacitance memory cell of claim 5 wherein the two OFETs are connected to each other at a junction, the capacitor being coupled to the junction, further including an output terminal coupled to the junction.

8. The organic capacitance memory cell of claim 5 wherein the two OFETs each have a gate electrode, further including an input terminal connected to each said gate electrode for selectively receiving an electrical pulse input signal for either charging or discharging the capacitor.
